(19) United States
(12) Patent Application Publication
(10) Pub. No.: US 2025/0293538 A1
(43) Pub. Date: Sep. 18, 2025

(54) WORK MACHINES AND METHOD OF OPERATING WORK MACHINES

(71) Applicant: Caterpillar Inc., Peoria, IL (US)

(72) Inventors: Jayneel H. Pandya; Dhanasekar Murugan, Peoria, IL (US); Qinyang Rao, Washington, IL (US); Baba Sharat Chandra Lingozi, Oro Valley, AZ (US)

(73) Assignee: Caterpillar Inc., Peoria, IL (US)

(21) Appl. No.: 18/608,379

(22) Filed: Mar. 18, 2024

(51) Int. Cl. H02J 7/34; H01M 10/613; H02J 7/00; H05K 7/20

(52) U.S. Cl. CPC H02J 7/342; H01M 10/613; H02J 7/0024; H02J 7/0047; H05K 7/20927; H05K 7/20945

(57) ABSTRACT

A work machine includes first and second battery systems and a controller. The first and second battery systems each include one or more batteries, and a thermal management system. The controller is operatively connected to the first and second battery systems and configured to operate the work machine in a full operation mode powered by the first and second battery systems, and on condition of an indication of a fault in one of the first and second battery systems, change an operating mode of the work machine from the full operation mode to a fault operation mode powered by the other of the first and second battery systems. The full operation mode requires a first minimum amount of electrical power that is greater than a second minimum amount of electrical power required for the fault operation mode.

### TECHNICAL FIELD

This disclosure relates generally, but not by way of limitation, to works machines powered wholly or in party by electrical power.

### BACKGROUND

Battery electric vehicles are a type of electric vehicle that rely solely on electric power stored in a battery module to propel and operate the machine. Hybrid vehicles combine internal combustion engines with electric motors. In both cases, the vehicles utilize electric motors powered by high-capacity battery modules, which provide the necessary energy to power various aspects of vehicle operation, for example to drive the vehicle's traction system.

The battery modules are commonly composed of multiple individual battery cells, such as lithium-ion or lithium-polymer, that store electrical energy chemically. These cells are interconnected and packaged together in a compact and robust unit, ensuring efficient energy storage and delivery. The size and capacity of battery modules vary depending on the specific machine and its intended use. Higher-capacity battery modules allow battery electric machines to operate longer on a single charge.

The batteries powering such vehicles generate heat, which affects efficiency and performance. Additionally, overheating of the batteries can lead to safety issues. As such, the battery modules of electric vehicles commonly include a thermal management system, which modulates the temperature of the batteries. In the event of a fault in the thermal management system, the vehicle may need to be serviced before continued use to avoid overheating of the batteries.

US Pub. No. 2023/0112971, entitled “COOLING ARRANGEMENT, MOTOR VEHICLE BATTERY, AND METHOD FOR OPERATING COOLING UNITS” discloses a cooling arrangement for cooling a cell arrangement comprising a plurality of cell units of a motor vehicle battery, wherein the cooling arrangement comprises a plurality of cooling units, wherein a respective one of the cooling units is associated with one of the cell units, and wherein the cooling units comprise a control device adapted to separately control a cooling capacity for a respective one of the cooling units.

### SUMMARY

In an example, a work machine includes first and second battery systems and a controller. The first and second battery systems each include one or more batteries, and a thermal management system fluidically connected to and configured to circulate a heat exchange fluid to regulate a temperature of the one or more batteries. The controller is operatively connected to the first and second battery systems and configured to operate the work machine in a full operation mode powered by the first and second battery systems, and on condition of an indication of a fault in one of the first and second battery systems, change an operating mode of the work machine from the full operation mode to a fault operation mode powered by the other of the first and second battery systems. The full operation mode requires a first minimum amount of electrical power that is greater than a second minimum amount of electrical power required for the fault operation mode.

In an example, a method for operating a work machine in multiple modes includes operating the work machine in a full power mode using first and second battery systems of the work machine, detecting a fault in one of the first and second battery systems, and changing an operating mode of the work machine from the full power mode to a low power mode powered by the other of the first and second battery systems. Each of the first and second battery systems includes one or more batteries, and a thermal management system fluidically connected to and configured to circulate a heat exchange fluid to regulate a temperature of the one or more batteries.

These and other examples and features of the present devices, systems, and methods will be set forth in part in the following Detailed Description. This overview is intended to provide a summary of subject matter of the present patent application. It is not intended to provide an exclusive or exhaustive explanation of the invention. The detailed description is included to provide further information about the present patent application.

### BRIEF DESCRIPTION OF THE DRAWINGS

In the drawings, which are not necessarily drawn to scale, like numerals may describe similar components in different views. Like numerals having different letter suffixes may represent different instances of similar components. The drawings illustrate generally, by way of example, but not by way of limitation, various embodiments discussed in the present document.

FIG. 1 is an elevation view schematically depicting an example system including a paving machine and a material transfer machine.

FIG. 2 is a plan view of an asphalt mat with centerline striping.

FIGS. 3A-3C are elevation views schematically depicting a screed system in different configurations.

FIG. 4 is a flowchart depicting an example method of operating a work machine in multiple modes.

### DETAILED DESCRIPTION

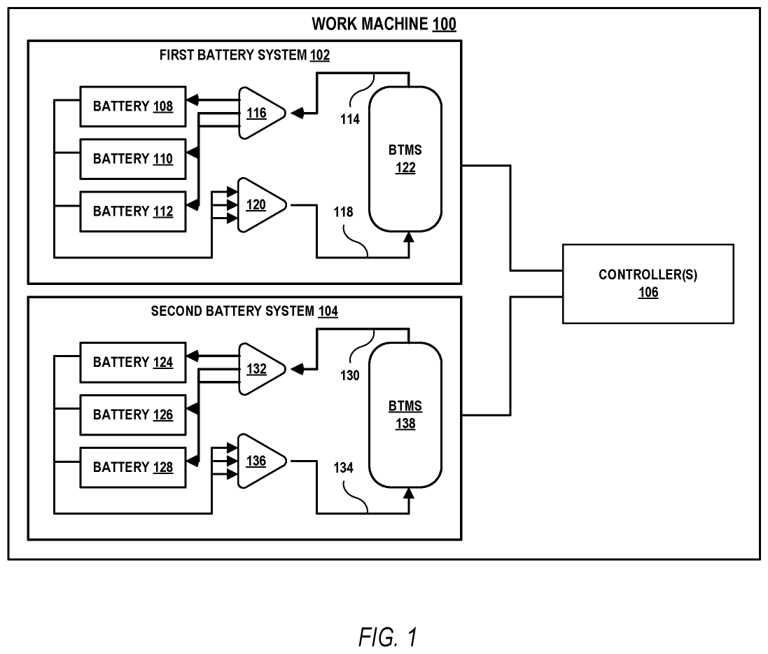

FIG. 1 is a block diagram depicting example work machine 100. Work machine 100 can include a variety of types of work machines powered wholly or in part by electrical power via a plurality of batteries. For example, work machine 100 can include work machines related to various industries, including, as examples, construction, agriculture, forestry, transportation, material handling, waste management, and so on. Work machine 100 can include, for example, a paving machine, cold planer, wheel loader, grader, scraper, dozer, excavator, compactor, material haulers like dump trucks, along with other example machine types.

Example work machine 100 includes first battery system 102, second battery system 104, and controller 106. First battery system 102 includes first battery 108, second battery 110, third battery 112, supply liquid circuit 114, supply manifold 116, return liquid circuit 118, return manifold 120, and first battery thermal management system (BTMS) 122. Second battery system 104 includes first battery 124, second battery 126, third battery 128, supply liquid circuit 130, supply manifold 132, return liquid circuit 134, return manifold 136, and second BTMS 138.

First battery system 102 and second battery system 104 are configured to supply power to one or more components of work machine 100, such as at least one traction component and/or at least one accessory component of the machine 100. Controller 106 is operatively connected to first battery system 102 and second battery system 104 and configured to control operation of work machine 100 in a number of modes using one or both of first battery system 102 and second battery system 104.

First BTMS 122 is fluidically connected to and configured to circulate a heat exchange fluid to regulate a temperature of first battery 108, second battery 110, and third battery 112 of first battery system 102. For example, BTMS 122 is fluidically connected to first battery 108, second battery 110, and third battery 112 via supply liquid circuit 114, supply manifold 116, return liquid circuit 118, and return manifold 120. A heat exchange fluid the temperature of which is modulated to a set point by BTMS 122 is supplied to first battery 108, second battery 110, and third battery 112 via supply liquid circuit 114 and supply manifold 116. After exchanging heat with first battery 108, second battery 110, and third battery 112, the heat exchange fluid is at a different temperature than the set point and is returned to first BTMS 122 via return liquid circuit 118 and return manifold 120.

Similarly, second BTMS 138 is fluidically connected to and configured to circulate a heat exchange fluid to regulate a temperature of first battery 124, second battery 126, and third battery 128 of second battery system 102. For example, BTMS 138 is fluidically connected to first battery 124, second battery 126, and third battery 128 via supply liquid circuit 130, supply manifold 132, return liquid circuit 134, and return manifold 136. A heat exchange fluid the temperature of which is modulated to a set point by second BTMS 138 is supplied to first battery 124, second battery 126, and third battery 128 via supply liquid circuit 130 and supply manifold 132. After exchanging heat with first battery 124, second battery 126, and third battery 128, the heat exchange fluid is at a different temperature than the set point and is returned to second BTMS 138 via return liquid circuit 134 and return manifold 136.

In examples, first BTMS 122 and second BTMS 138 are configured to cool the heat exchange fluid, which in turn absorbs heat and thereby cools of the batteries of first battery system 102 and second battery system 104. In such cases, the supply side is a cool liquid supply and the return is a hot liquid return and the BTMS includes a chiller or other heat exchanger configured to lower a temperature of the heat exchange fluid. In other examples, first BTMS 122 and second BTMS 138 are configured to heat the heat exchange fluid, which in turn rejects heat and thereby heats the batteries of first battery system 102 and second battery system 104. In such cases, the supply side is a hot liquid supply and the return is a cool (relatively) liquid return and the BTMS includes a heater or other heat exchanger configured to raise a temperature of the heat exchange fluid.

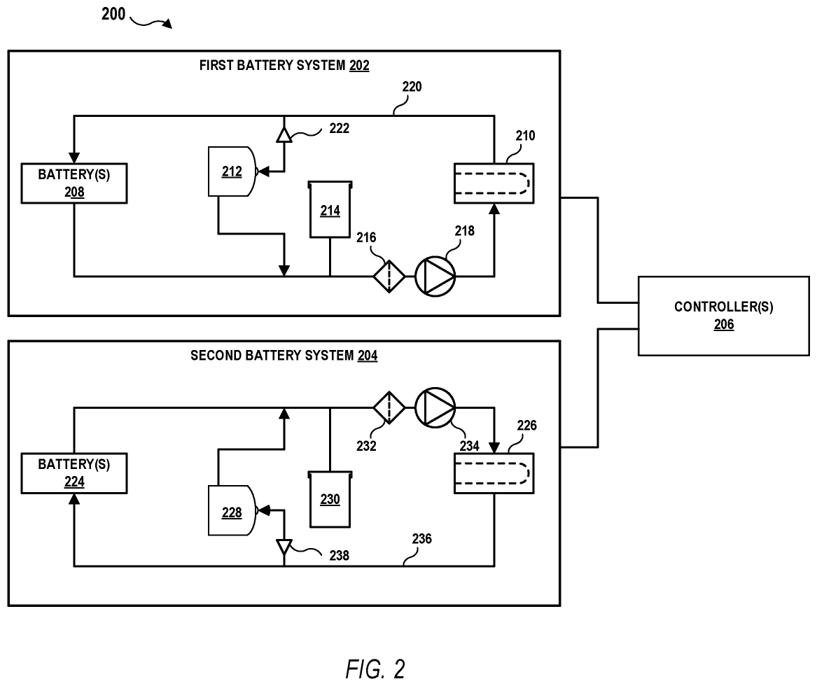

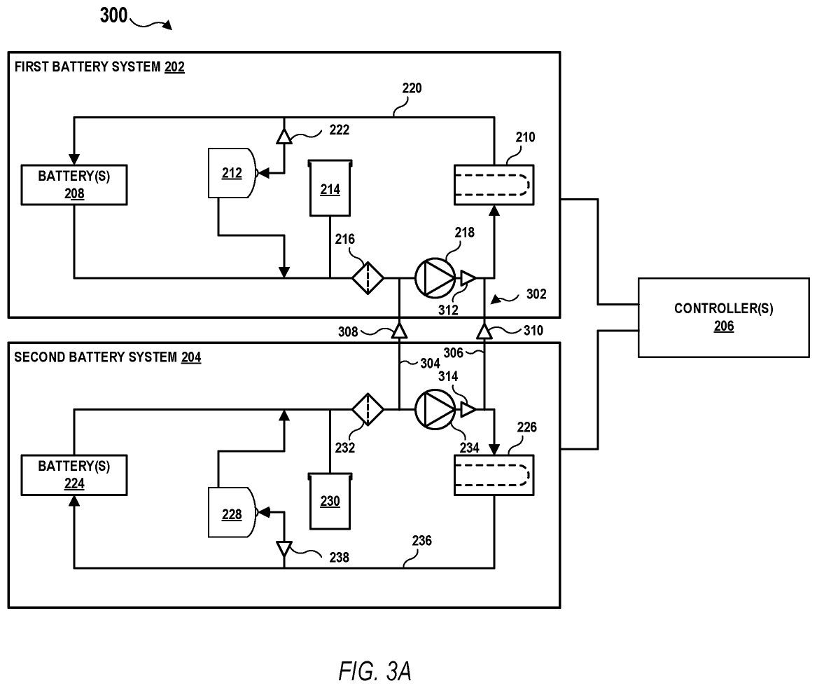

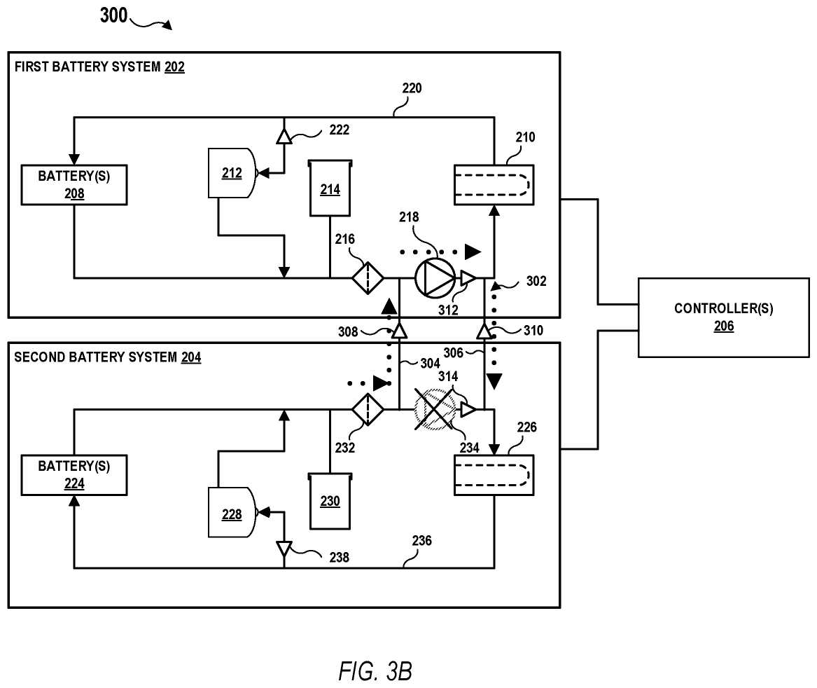

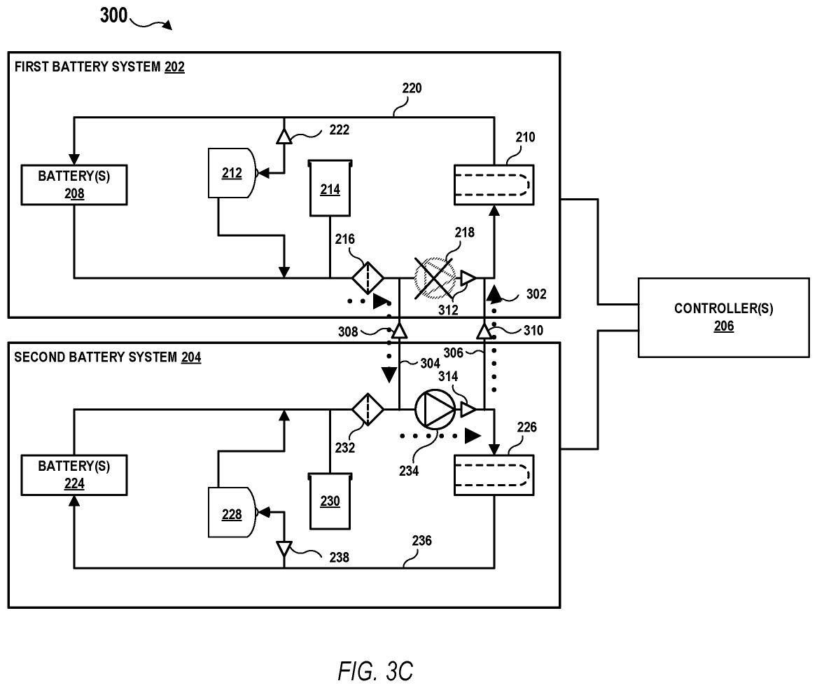

As is the case with the examples of FIGS. 2 and 3A-3C, first BTMS 122 and second BTMS 138 can include a number of components, including pumps, filters, manifolds, valves, chillers, heaters and/or other heat exchangers by which each BTMS circulates the heat exchange fluid to regulate the temperature of the batteries to which it is connected.

Work machine 100 is configured to be operated in multiple modes, which can include multiple power modes defined by a minimum amount of electrical power required to power operation of the machine using first battery system 102 and/or second battery system 104. In examples, controller 106 is configured to control work machine 100 to operate in a full operation mode (also referred to as full power mode) or a fault operation mode (also referred to as low power mode) depending upon an operational capability of first battery system 102 and second battery system 104.

For example, controller 106 is configured to deactivate one of first battery system 102 and second battery system 104 based on an indication of a fault in one of first battery system 102 and second battery system 104 and change the operating mode of work machine 100 from the full operation mode to the fault operation mode. The full operation mode of work machine 100 requires a first minimum amount of electrical power, which is greater than a second minimum amount of electrical power required in the fault operation mode.

To ensure continued operation of work machine 100 in both the full operation mode and the fault operation mode, each of first battery system 102 and second battery system 104 includes a separate battery thermal management system (BTMS) 106, 108 to reject heat generated by the batteries. Additionally, each of first battery system 102 and second battery system 104 is configured to deliver to work machine 100 equal to or greater than the second minimum amount of electrical power required for the fault operation mode.

FIG. 2 is a block diagram depicting example power system 200, which can be employed in a variety of types of work machines powered wholly or in part by electrical power via a plurality of batteries. Example system 200 includes first battery system 202, second battery system 204, and controller 206. First battery system 202 includes one or more batteries 208 and a first battery thermal management system (BTMS1) including chiller 210, heater 212, shunt tank 214, filter 216, and pump 218, interconnected with one another and battery(s) 208 via liquid circuit 220 and bypass valve 222. Second battery system 204 includes one or more batteries 224 and a second battery thermal management system (BTMS2) including chiller 226, heater 228, shunt tank 230, filter 232, and pump 234, interconnected with one another and battery(s) 224 via liquid circuit 236 and bypass valve 238.

Controller 206 is operatively connected to first battery system 202 and second battery system 204 and configured to control operation of a work machine in a number of modes. As with the example of FIG. 1, system 200 is configured to such that in the event of a fault in either first battery system 202 or second battery system 204, controller 206 can continue operation of the work machine in a fault operation/low power mode, which can allow the fault to be investigated and remedied, after which the work machine can return to normal operation in a full operation/full power mode.

Example system 200 includes additional details of example an BTMS employed in examples according to this disclosure to circulate a heat exchange fluid to regulate a temperature of batteries power some or all of the operation of a work machine. In FIG. 2, BTMS1 is fluidically connected to and configured to circulate a heat exchange fluid to regulate a temperature of battery(s) 208. Pump 218 circulates the heat exchange fluid through chiller 210 and/or heater 212 via liquid circuit 220, and bypass valves 221 and 222 control flow of the liquid through heater 212. For example, in some ambient conditions and/or set point temperatures of the heat exchange fluid, bypass valve 222 is closed and the heat exchange fluid is circulated from chiller 210 to battery(s) 208 and back to chiller 210 through filter 216. In other ambient conditions and/or set point temperatures of the heat exchange fluid, bypass valve 222 is open, chiller 210 is deactivated and the heat exchange fluid is circulated through deactivated chiller 210 without any heat exchange and through heater 212, which heats the heat exchange fluid circulated through battery(s) and back to chiller 210 through filter 216. In some cases, the fluid may circulate through and exchange heat in both chiller 210 and heater 212 to modulate the temperature of the heat exchange fluid in an efficient manner.

Shunt tank 214 is fluidically connected to liquid circuit 220. Shunt tank 214 can be employed to purge air from BTMS1, fill BTMS1 with the heat exchange fluid, and to regulate the fluid pressure of the system. For example, shunt tank 214 can include valves, which, as the heat exchange fluid expands in BTMS1, keep pressure regulated at a constant head pressure. BTMS2 is fluidically connected to and configured to circulate a heat exchange fluid to regulate a temperature of battery(s) 224 in a similar manner as BTMS1.

The work machine that employs system 200 is configured to be operated in multiple modes, which can include multiple power modes defined by a minimum amount of electrical power required to power operation of the machine using first battery system 202 and/or second battery system 204. In examples, controller 206 is configured to control the work machine to operate in a full operation/power mode or a fault operation/low power mode depending upon an operational capability of first battery system 202 and second battery system 204.

For example, controller 206 is configured to deactivate one of first battery system 202 and second battery system 204 based on an indication of a fault in one of first battery system 202 and second battery system 204. In an example, first battery system 202 and second battery system 204 include one more sensors monitoring aspects of operation of the respective systems and communicatively connected to controller 206. Such sensor(s) can send signals to controller 206 indicative of faults, malfunctions, etc. in first battery system 202 and second battery system 204. As an example, the battery systems can include temperature and pressure sensors monitoring the temperature and pressure of the heat exchange fluid circulated by the BTMS. In an example, controller 206 detects a fault in a battery system upon receiving signals from either or both of the temperature and pressure sensors indicating deviation from set point/target/desired values. Failure of pump 218, could, for example, be detected by a loss of pressure. Failure or malfunction of chiller 210 and/or heater 214 could be detected by a departure of temperature from a target set point. A variety of other sensors or other devices or systems can be employed to detect fault conditions in example battery systems according to this disclosure.

In the event of a fault in one of first battery system 202 and second battery system 204, controller 206 can change the operating mode of the work machine from the full operation/power mode to the fault operation/low power mode. The full operation mode of the work machine requires a first minimum amount of electrical power, which is greater than a second minimum amount of electrical power required in the fault operation mode.

Controller 206 can control operation of the work machine in a variety of ways in the fault operation/low power mode. For example, controller 206 may limit the rate of travel and/or the use of implements or other sub-systems of the work machine. For example, controller 206 can control the work machine in a limp home routine in which some or all electrically powered implements, accessories, and other sub-systems are deactivated, and the machine is driven with or without operator control to a predetermined or ad-hoc location at a fixed speed. In an example, controller 206 can control the work machine in a de-rate routine in which the rate of travel of the work machine is limited to a relatively low speed.

To ensure continued operation of the work machine in both the full operation mode and the fault operation mode, each of first battery system 202 and second battery system 204 includes a separate battery thermal management system (BTMS1 and BTMS2) to reject heat generated by the batteries. Additionally, each of first battery system 202 and second battery system 204 is configured to deliver to the work machine equal to or greater than the second minimum amount of electrical power required for the fault operation mode.

In the example of FIG. 2, first battery system 202 includes one or more battery(s) 208 and second battery system 204 includes one or more battery(s) 224. In examples according to this disclosure, regardless of the number of batteries in each separate and independent battery system, the total power of the battery(s) is equal to or greater than the second minimum amount of electrical power required for the fault operation mode such that the work machine can continue some operation in the event of a fault in the systems powering the machine or portions thereof.

FIGS. 3A-3C are block diagrams depicting example power system 300, which can be employed in a variety of types of work machines powered wholly or in part by electrical power via a plurality of batteries. Referring to FIG. 3A, system 300 is substantially similar to example system 200 with the addition of fluid bypass circuit 302, which fluidically couples first battery system 202 and second battery system 204 and is arranged and configured to bypass a failed or malfunctioning pump of either system while continuing operation of both systems.

Example system 300 includes first battery system 202, second battery system 204, and controller 206. First battery system 202 includes one or more batteries 208 and a first battery thermal management system (BTMS1) including chiller 210, heater 212, shunt tank 214, filter 216, and pump 218, interconnected with one another and battery(s) 208 via liquid circuit 220 and bypass valve 222. Second battery system 204 includes one or more batteries 224 and a second battery thermal management system (BTMS2) including chiller 226, heater 228, shunt tank 230, filter 232, and pump 234, interconnected with one another and battery(s) 224 via liquid circuit 236 and bypass valve 238.

Controller 206 is operatively connected to first battery system 202 and second battery system 204 and configured to control operation of a work machine in a number of modes. As with the examples of FIGS. 1 and 2, system 300 is configured to such that in the event of a fault in either first battery system 202 or second battery system 204, controller 206 can continue operation of the work machine in a fault operation/low power mode, which can allow the fault to be investigated and remedied, after which the work machine can return to normal operation in a full operation/full power mode.

BTMS1 is fluidically connected to and configured to circulate a heat exchange fluid to regulate a temperature of battery(s) 208. Pump 218 circulates the heat exchange fluid through chiller 210 and/or heater 212 via liquid circuit 220, and bypass valves 221 and 222 control flow of the liquid through heater 212. For example, in some ambient conditions and/or set point temperatures of the heat exchange fluid, bypass valve 222 is closed and the heat exchange fluid is circulated from chiller 210 to battery(s) 208 and back to chiller 210 through filter 216. In other ambient conditions and/or set point temperatures of the heat exchange fluid, bypass valve 222 is open, chiller 210 is deactivated and the heat exchange fluid is circulated through deactivated chiller 210 without any heat exchange and through heater 212, which heats the heat exchange fluid circulated through battery(s) and back to chiller 210 through filter 216. In some cases, the fluid may circulate through and exchange heat in both chiller 210 and heater 212 to modulate the temperature of the heat exchange fluid in an efficient manner.

Shunt tank 214 is fluidically connected to liquid circuit 220. Shunt tank 214 can be employed to purge air from BTMS1, fill BTMS1 with the heat exchange fluid, and to regulate the fluid pressure of the system. For example, shunt tank 214 can include valves, which, as the heat exchange fluid expands in BTMS1, keep pressure regulated at a constant head pressure. BTMS2 is fluidically connected to and configured to circulate a heat exchange fluid to regulate a temperature of battery(s) 224 in a similar manner as BTMS1.

The work machine that employs system 300 is configured to be operated in multiple modes, which can include multiple power modes defined by a minimum amount of electrical power required to power operation of the machine using first battery system 202 and/or second battery system 204. In examples, controller 206 is configured to control the work machine to operate in a full operation/power mode or a fault operation/low power mode depending upon an operational capability of first battery system 202 and second battery system 204.

For example, controller 206 is configured to deactivate one of first battery system 202 and second battery system 204 based on an indication of a fault in one of first battery system 202 and second battery system 204. In an example, first battery system 202 and second battery system 204 include one more sensors monitoring aspects of operation of the respective systems and communicatively connected to controller 206. Such sensor(s) can send signals to controller 206 indicative of faults, malfunctions, etc. in first battery system 202 and second battery system 204. As an example, the battery systems can include temperature and pressure sensors monitoring the temperature and pressure of the heat exchange fluid circulated by the BTMS. Failure of pump 218, could, for example, be detected by a loss of pressure. Failure or malfunction of chiller 210 and/or heater 214 could be detected by a departure of temperature from a target set point. A variety of other sensors or other devices or systems can be employed to detect fault conditions in example battery systems according to this disclosure.

In the event of a fault in one of first battery system 202 and second battery system 204, controller 206 can change the operating mode of the work machine from the full operation/power mode to the fault operation/low power mode. The full operation mode of the work machine requires a first minimum amount of electrical power, which is greater than a second minimum amount of electrical power required in the fault operation mode.

Controller 206 can control operation of the work machine in a variety of ways in the fault operation/low power mode. For example, controller 206 may limit the rate of travel and/or the use of implements or other sub-systems of the work machine. For example, controller 206 can control the work machine in a limp home routine in which some or all electrically powered implements, accessories, and other sub-systems are deactivated, and the machine is driven with or without operator control to a predetermined or ad-hoc location at a fixed speed. In an example, controller 206 can control the work machine in a de-rate routine in which the rate of travel of the work machine is limited to a relatively low speed.

To ensure continued operation of the work machine in both the full operation mode and the fault operation mode, each of first battery system 202 and second battery system 204 includes a separate battery thermal management system (BTMS1 and BTMS2) to reject heat generated by the batteries. Additionally, each of first battery system 202 and second battery system 204 is configured to deliver to the work machine equal to or greater than the second minimum amount of electrical power required for the fault operation mode.

In the example of FIG. 3A, first battery system 202 includes one or more battery(s) 208 and second battery system 204 includes one or more battery(s) 224. In examples according to this disclosure, regardless of the number of batteries in each separate and independent battery system, the total power of the battery(s) is equal to or greater than the second minimum amount of electrical power required for the fault operation mode such that the work machine can continue some operation in the event of a fault in the systems powering the machine or portions thereof.

System 300 includes fluid bypass circuit 302, which fluidically couples first battery system 202 and second battery system 204 and is arranged and configured to bypass a failed or malfunctioning pump of either system while continuing operation of both systems. As noted, failure of pump 218 of first battery system 202 or pump 234 of second battery system 204, could, for example, be detected by a loss of pressure. System 300, versus system 200, includes fluid bypass circuit 302, by which a pump failure or malfunction can be ameliorated.

Fluid bypass circuit 302 includes first and second bypass conduits 304, 306 and bypass valves 308-314. First and second bypass conduits are arranged on and fluidically connected toward inlet and outlet ends of pump 218 of first battery system 202 or pump 234 of second battery system 204. Bypass valve 308 is in fluid circuit 220 of first battery system 202 toward the outlet end of pump 218. Bypass valve 310 is in fluid circuit 220 of first battery system 202 toward the outlet end of pump 218. Bypass valve 312 is in fluid circuit 236 of second battery system 204 toward the outlet end of pump 234.

In normal operation of system 300 with both pump 218 and pump 234 operating, bypass valves 308 and 310 are closed and bypass valves 312 and 314 are open. Referring to FIG. 3B, in the event of failure of pump 234 of second battery system 204, controller 206 can control bypass valves 308 and 310 to open and control bypass valve 314 to close, which will bypass faulty pump 234 and continue circulation of the heat exchange fluid through both BTMS1 and BTMS2 using pump 218. Similarly, referring to FIG. 3C, in the event of failure of pump 218 of first battery system 202, controller 206 can control bypass valves 308 and 310 to open and control bypass valve 312 to close, which will bypass faulty pump 218 and continue circulation of the heat exchange fluid through both BTMS1 and BTMS2 using pump 234.

Battery systems in accordance with examples of this disclosure can include a plurality of battery strings, such as three battery strings. In some examples, there may be more than three battery strings and in other examples, there may be fewer. Each battery string can include one or more batteries or battery modules having at least one battery cell. The batteries can include a variety of types of rechargeable batteries that store electrical energy chemically, including lithium-ion or lithium-polymer, solid state, sodium ion, lithium iron phosphate, lithium titanate oxide (LTO), as examples.

Heat exchange fluids used in examples according to this disclosure can include a variety of types of such fluids. For example, BTMS can employ glycols, low conductivity coolants, and/or water. Additionally, the chiller (or other type of heat exchanger) included in the BTMS may employ a variety of refrigerants. Additionally, although some examples have been described and are configured to employ a liquid heat exchange fluid, e.g. the examples of FIGS. 2-3C, in other examples according to this disclosure a BTMS could employ an air exchange system to manage the temperature of batteries of a work machine. In such cases, the fluid circuits can be replaced by air plenums and ducts, valves by dampers, and pumps by fans, as examples.

Controllers in accordance with examples of this disclosure, including controller(s) 106 and 206 can be included in or separate from a work machine. Examples according to this disclosure may include multiple controllers working in conjunction with each other to execute functions attributed to the controller(s). In examples, controller(s) can be part of or included in an electronic control unit ECU of the work machine.

Controller(s), ECUs, etc. included in examples according to this disclosure can be configured to communicate with one another and with other components of the work machine (e.g., first battery system 102/202 and second battery system 104/204) via various wired or wireless communications technologies and components using various public and/or proprietary standards and/or protocols. Examples of transport mediums and protocols for electronic communication between components of the work machine machine include Ethernet, Transmission Control Protocol/Internet Protocol (TCP/IP), IEEE 802.11 or Bluetooth, or other standard or proprietary transport mediums and communication protocols.

In some examples, controller(s) can be included in an ECU of the work machine. An electronic control unit (ECU) can be an embedded system that controls various aspects of machine operation. Types of ECUs include Electronic/Engine Control Module, Powertrain Control Module, Transmission Control Module, Brake Control Module, Suspension Control Module, among other examples. In the case of industrial, construction, and other heavy machinery, example ECUs can also include an Implement Control Module associated with one or more implements connected to and operable from the machine.

Work machines in accordance with examples of this disclosure may include, for example, an Engine Control Module (ECM), an Implement Control Module (ICM), a Transmission Control Module (TCM), and a Brake Control Module (BCM). These electronic modules/units can be communicatively connected and configured to send and receive data, sensor or other digital and/or analog signals, and other information between the various ECUs of machine 100. Additionally, functions attributed to an ECU or controller(s) 106, can be distributed among multiple devices.

Controller(s), whether onboard and/or separate from the work machine, can include software, hardware, and combinations of hardware and software configured to execute a number of functions attributed to the components in the disclosed examples. Such controllers in examples according to this disclosure can be an analog, digital, or combination analog and digital controller including a number of components. As examples, the controller(s) can include integrated circuit boards or ICB(s), printed circuit boards PCB(s), processor(s), data storage devices, switches, relays, etcetera. Examples of processors can include any one or more of a microprocessor, a controller, a digital signal processor (DSP), an application specific integrated circuit (ASIC), a field-programmable gate array (FPGA), or equivalent discrete or integrated logic circuitry.

Controller(s), ECUs and other electronic controls in examples according to this disclosure can include storage media to store and/or retrieve data or other information, for example, signals from sensors. Examples of non-volatile storage devices include magnetic hard discs, optical discs, floppy discs, flash memories, or forms of electrically programmable memories (EPROM) or electrically erasable and programmable (EEPROM) memories. Examples of volatile storage devices include random access memories (RAM), dynamic random access memories (DRAM), static random access memories (SRAM), and other forms of volatile storage devices. The data storage devices can be used to store program instructions for execution by processor(s) of, for example, the controller(s).

### Industrial Applicability

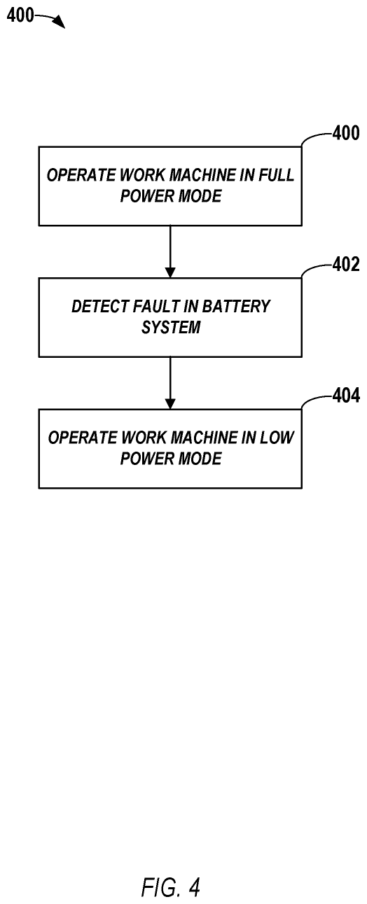

FIG. 4 is a flowchart depicting example method 500 for operating a work machine in multiple modes. Example method 400 includes operating a work machine in a full power mode using first and second battery systems of the work machine (402), detecting a fault in one of the first and second battery systems (404), and changing an operating mode of the work machine from the full power mode to a low power mode powered by the other of the first and second battery systems (406).

In an example, a work machine includes power system 300 having first battery system 202, second battery system 204, controller 206, and fluid bypass circuit 302. The work machine is engaged in operation at a work site. For example, the excavator work machine is operating under the power of first battery system 202 and second battery system 204 to excavate material from one location of the work site and deposit the material at another location. During such operations, controller 206 controls system 300 and the work machine to operate in a full power mode, in which power is supplied to various systems of the work machine by first battery system 202 and second battery system 204.

As the work machine conducts excavation operations, controller 206 receives a signal from a pressure sensor of BTMS1 of first battery system 202, which indicates a sudden loss of pressure in fluid circuit 220. The fault indicated by the signal received by controller 206 can include failure or malfunction of pump 218 of BTMS1 of first battery system 202. With or without additional inspection from an operator, controller 206 can control bypass valves 308 and 310 to open and control bypass valve 312 to close, which, as depicted in FIG. 3C will bypass faulty pump 218 and continue circulation of the heat exchange fluid through both BTMS1 and BTMS2 using pump 234. In the event the pressure loss signal ceases, the work machine can return to normal/full operation.

As the work machine continues excavation operations, controller receives a signal from a temperature sensor of BTMS1 of first battery system 202, which indicates a fault in operation of battery(s) 208 and/or BTMS1. In response to the indication of a fault in first battery system 202, controller 206 changes the operating mode of the work machine from the full power mode to a low power mode powered by second battery system 204. Additionally, controller 206 controls bypass valves 308 and 310 to close to cause the heat exchange fluid to circulate through only second battery system 204.

As an example of operation of the work machine in the low power mode, controller 206 limits the speed of travel of the work machine to a relatively low maximum speed and shuts down operation of non-essential sub-systems, accessories, implements, etc., while the operator drives the work machine to a service location at the work site or a transport location for off-site service.

In the foregoing Detailed Description, it can be seen that various features are grouped together in a single example for the purpose of streamlining the disclosure. This method of disclosure is not to be interpreted as reflecting an intention that the claimed examples require more features than are expressly recited in each claim. Rather, as the following claims reflect, inventive subject matter lies in less than all features of a single disclosed example. Thus, the following claims are hereby incorporated into the Detailed Description, with each claim standing on its own as a separate example.

Note that not all of the activities or elements described above in the general description are required, that a portion of a specific activity or device may not be required, and that one or more further activities may be performed, or elements included, in addition to those described. Still further, the order in which activities are listed are not necessarily the order in which they are performed. Also, the concepts have been described with reference to specific examples. However, one of ordinary skill in the art appreciates that various modifications and changes can be made without departing from the scope of the present disclosure as set forth in the claims below. Accordingly, the specification and figures are to be regarded in an illustrative rather than a restrictive sense, and all such modifications are intended to be included within the scope of the present disclosure. Benefits, other advantages, and solutions to problems have been described above with regard to specific examples. However, the benefits, advantages, solutions to problems, and any feature(s) that may cause any benefit, advantage, or solution to occur or become more pronounced are not to be construed as a critical, required, or essential feature of any or all the claims. Moreover, the particular examples disclosed above are illustrative only, as the disclosed subject matter may be modified and practiced in different but equivalent manners apparent to those skilled in the art having the benefit of the teachings herein. No limitations are intended to the details of construction or design herein shown, other than as described in the claims below. It is therefore evident that the particular examples disclosed above may be altered or modified and all such variations are considered within the scope of the disclosed subject matter. Accordingly, the protection sought herein is as set forth in the claims below.

What is claimed is:

1. A work machine comprising:
first and second battery systems, each of which comprises:
one or more batteries; and
a thermal management system fluidically connected to and configured to circulate a heat exchange fluid to regulate a temperature of the one or more batteries; and
a controller operatively connected to the first and second battery systems and configured to:
operate the work machine in a full operation mode powered by the first and second battery systems; and
on condition of an indication of a fault in one of the first and second battery systems, change an operating mode of the work machine from the full operation mode to a fault operation mode powered by the other of the first and second battery systems.

2. The work machine of claim 1, wherein the full operation mode requires a first minimum amount of electrical power that is greater than a second minimum amount of electrical power required for the fault operation mode.

3. The work machine of claim 2, wherein a power rating of the one or more batteries of each of the first and second battery systems is equal to or greater than the second minimum amount of electrical power required for the fault operation mode.

4. The work machine of claim 1, wherein the controller is configured to:
deactivate the one of the first and second battery systems; and
control the other of the first and second battery systems to supply power to the work machine in the fault operation mode.

5. The work machine of claim 1, wherein the first and second battery systems each include a plurality of batteries.

6. The work machine of claim 1, wherein the one or more batteries of the first and second battery systems are selected from the group consisting of lithium-ion batteries, lithium-polymer batteries, solid state batteries, sodium ion batteries, lithium iron phosphate batteries, lithium titanate oxide (LTO) batteries, and combinations thereof.

7. The work machine of claim 1, wherein the thermal management system of each of the first and second battery systems comprises including a chiller, a heater, and a pump interconnected with one another and the one or more batteries by a liquid circuit through which the heat exchange fluid flows.

8. The work machine of claim 7, further comprising a fluid bypass circuit fluidically coupled to and arranged and configured to bypass the pump of either of the first and second battery systems.

9. A work machine comprising:
a plurality of battery systems, each of the plurality of battery systems comprising:
one or more batteries; and
a thermal management system fluidically connected to and configured to circulate a heat exchange fluid to regulate a temperature of the one or more batteries; and
a controller operatively connected to the plurality of battery systems and configured to control operation of the work machine in a full power mode or a low power mode using one or more of the plurality of battery systems, wherein:
the full power mode requires a first minimum amount of electrical power that is greater than a second minimum amount of electrical power of the lower mode; and
each of the plurality of battery systems is configured to deliver to the work machine equal to or greater than the second minimum amount of electrical power of the lower mode.

10. The work machine of claim 9, wherein the controller is configured to:
operate the work machine in the full power mode powered by the plurality of battery systems; and
on condition of an indication of a fault in one of the plurality of battery systems, change an operating mode of the work machine from the full power mode to the low power mode.

11. The work machine of claim 10, wherein the controller is configured to:
deactivate the one of the plurality of battery systems based on the indication of the fault; and
control the other of the plurality of battery systems to supply power to the work machine in the low power mode.

12. The work machine of claim 9, wherein the plurality of battery systems each include a plurality of batteries.

13. The work machine of claim 9, wherein the one or more batteries of the plurality of battery systems are selected from the group consisting of lithium-ion batteries, lithium-polymer batteries, solid state batteries, sodium ion batteries, lithium iron phosphate batteries, lithium titanate oxide (LTO) batteries, and combinations thereof.

14. The work machine of claim 9, wherein the thermal management system of each of the plurality of systems comprises including a chiller, a heater, and a pump interconnected with one another and the one or more batteries by a liquid circuit through which the heat exchange fluid flows.

15. The work machine of claim 14, wherein the plurality of battery systems comprises first and second battery systems, and further comprising a fluid bypass circuit fluidically coupled to and arranged and configured to bypass the pump of either of the first and second battery systems.

16. A method for operating a work machine in multiple modes, the method comprising:
operating the work machine in a full power mode using first and second battery systems of the work machine, each of the first and second battery systems comprising:
one or more batteries; and
a thermal management system fluidically connected to and configured to circulate a heat exchange fluid to regulate a temperature of the one or more batteries;
detecting a fault in one of the first and second battery systems; and
changing an operating mode of the work machine from the full power mode to a low power mode powered by the other of the first and second battery systems.

17. The method of claim 16, wherein the full power mode requires a first minimum amount of electrical power that is greater than a second minimum amount of electrical power required for the low power mode.

18. The method of claim 17, wherein a power level of the one or more batteries of each of the first and second battery systems is equal to or greater than the second minimum amount of electrical power of the low power mode.

19. The method of claim 16, further comprising:
deactivating the one of the first and second battery systems; and
controlling the other of the first and second battery systems to supply power to the work machine in the fault operation mode.

20. The method of claim 16, wherein the first and second battery systems each include a plurality of batteries.

21. The method of claim 16, wherein the one or more batteries of the first and second battery systems are selected from the group consisting of lithium-ion batteries, lithium-polymer batteries, solid state batteries, sodium ion batteries, lithium iron phosphate batteries, lithium titanate oxide (LTO) batteries, and combinations thereof.

22. The method of claim 16, wherein the thermal management system of the first battery system includes a first pump and the thermal management system of the second battery system includes a second pump, and further comprising:
determining one of the first pump or the second pump has malfunctioned; and
bypassing the one of the first pump or the second pump to continue circulating the heat exchange fluid through the thermal management systems of both of the first battery system and the second battery system using the other of the first pump or the second pump.
